(19) United States
(12) Patent Application Publication
(10) Pub. No.: US 2020/0309825 A1
(43) Pub. Date: Oct. 1, 2020

(54) SYSTEMS AND METHODS FOR MANAGING AN ELECTRICAL LOAD OF A POWER STRIP

(71) Applicant: LEVITON MANUFACTURING CO., INC., Melville, NY (US)

(72) Inventors: Fernando Arredondo, Melville, NY (US); Eugene Frid, Melville, NY (US); Kevin Shea, Melville, NY (US); Steven Caramico, Melville, NY (US)

(21) Appl. No.: 16/642,051

(22) PCT Filed: Sep. 13, 2018
(86) PCT No.: PCT/US2018/050876

§ 371 Date: Feb. 26, 2020

(51) Int. Cl. G01R 19/165; H01R 13/66

(52) U.S. Cl. CPC G01R 19/16547; H01R 13/6691; H01R 13/6683

(57) ABSTRACT

Systems and methods for managing an electrical load of a power strip. The systems include a power strip including an electrical connector connected to an AC power supply, outlet sockets electrically coupled to the electrical connector, a conductive path between the electrical connector and the electrical outlet sockets, an indicator, and a current monitoring circuit. The current monitoring circuit is electrically coupled to the conductive path and measures total current flowing in the conductive path, determines whether the total current is within a predetermined amount of current from a current rating of the power strip, and causes the indicator to indicate when the total current is within a predetermined amount of current from the current rating.

### CROSS REFERENCE TO RELATED APPLICATION

This application is a national phase of PCT Application No. PCT/US2018/050876 filed on Sep. 13, 2018, the entire disclosure of which is incorporated by reference herein.

### BACKGROUND

All residential and commercial buildings have wall outlets for powering AC-powered devices, such as lights, appliances, electronic devices, computers, and mobile devices. The AC-powered devices typically have a power cord with a plug configured to be connected to and removed from the wall outlet.

A wall outlet includes a female connector with slots or holes. The slots are configured to receive a male connector often referred to as a plug. The plug has protruding prongs, blades, or pins that fit into matching slots in the wall outlet. The wall outlet is enclosed by a cover typically called a wall plate, face plate, outlet cover, socket cover, or wall cover. Different countries have different national standards for wall outlets. The national standards differ by voltage rating, current rating, connector shape, connector size, and connector type.

A number of standards and solutions have been developed for providing power to medical devices in a hospital environment. Examples of these standards include UL 60601-1 and UL 1363. For some medical device applications, these standards require an uninterrupted power source. As several medical devices can share the same power source, the total current consumption must stay below a power source's rated current. Otherwise, a circuit breaker or similar device for limiting current may be triggered and disrupt power.

### SUMMARY

Embodiments of the present disclosure are described in detail with reference to the drawing figures wherein like reference numerals identify similar or identical elements.

An aspect of the present disclosure features a power strip. The power strip includes an electrical connector connected to an AC power supply, outlet sockets electrically coupled to the electrical connector, a conductive path between the electrical connector and the electrical outlet sockets, an indicator, and a current monitoring circuit. The current monitoring circuit is electrically coupled to the conductive path and is configured to: measure total current flowing through the conductive path; determine whether the total current is within a predetermined amount of current from a current rating of the power strip, and cause the indicator to indicate when the total current is within a predetermined amount of current from the current rating. In an aspect of the present disclosure, the current monitoring circuit determines whether the total current is within the predetermined amount of current by determining whether the total current exceeds a predetermined threshold, and the predetermined threshold is a percentage of the current rating of the power strip.

In an aspect of the present disclosure, the predetermined threshold is a first predetermined threshold, and the current monitoring circuit further determines whether the total current exceeds a second predetermined threshold less than the first predetermined threshold, and causes the indicator to indicate that the total current exceeds the second predetermined threshold.

In an aspect of the present disclosure, the current monitoring circuit further determines whether the total current exceeds a third predetermined threshold current that is lower than the second predetermined threshold, and causes the indicator to indicate that the total current exceeds the third predetermined threshold.

In an aspect of the present disclosure, the current monitoring circuit further determines whether the total current exceeds a third predetermined threshold current that is lower than the second predetermined threshold, and causes the indicator to indicate that the total current exceeds the third predetermined threshold.

In an aspect of the present disclosure, the current rating of the power strip is a maximum current rating. In aspects, the current monitoring circuit comprises a current sensor, an amplifier, and a comparator, and the current sensor is electrically coupled to the conductive path and the amplifier is electrically coupled to the current sensor and the comparator. In yet another aspect of the present disclosure, the current monitoring circuit comprises one or more of a resistor, a current transformer, a Hall effect sensor, or a Rogowski coil. In another aspect of the present disclosure, the indicator is an audible or a visible indicator. In another aspect of the present disclosure, the indicator is an LED configured to flash at a rate or change color based on a difference between the total current and the current rating of the power strip.

In another aspect of the present disclosure, the power strip further includes a communication circuit coupled to the current monitoring circuit and provides an indicator signal to a mobile device, a network, or a computer system when the total current is within a predetermined amount of current from the current rating. In an aspect of the present disclosure, the power strip is a medical-grade power strip.

In another aspect of the present disclosure, the current monitoring circuit further determines whether the total current is not within the predetermined amount of current from the current rating, and causes the indicator to indicate that the total current is not within the predetermined amount of current from the current rating. In another aspect of the present disclosure, the power strip further includes a plurality of lockable covers configured to cover the plurality of outlet sockets, respectively. In an aspect of the present disclosure, the power strip includes a circuit breaker configured to break the conductive path if an over current condition is detected.

An aspect of the present disclosure features a method of managing an electrical load of a power strip. The method includes sensing a total current flowing in a conductive path coupling a plurality of outlet sockets to an electrical connector of the power strip, determining whether the total current is within a predetermined amount of current from a current rating of the power strip, and causing an indicator to indicate when the total current is within a predetermined amount of current from the current rating.

In an aspect of the present disclosure, sensing the total current includes amplifying a sensor signal, and determining whether the total current is within a predetermined amount of current includes comparing the amplified sensor signal to a predetermined threshold to determine whether the total current exceeds a predetermined threshold.

In another aspect of the present disclosure, the method further includes providing an indicator signal to a mobile device, a network, or a computer system when the total current is within a predetermined amount of current from the current rating.

In another aspect of the present disclosure, the method further includes determining whether the total current is not within the predetermined amount of current from the current rating, and causing the indicator to indicate that the total current is not within the predetermined amount of current from the current rating.

In a further aspect of the present disclosure, sensing total current includes sensing total current using a current sensor, an amplifier, and a comparator, wherein the current sensor is electrically coupled to the conductive path and the amplifier is electrically coupled to the current sensor and the comparator.

In yet another aspect of the present disclosure, causing an indicator to indicate when the total current is within a predetermined amount of current from the current rating includes causing an audible or a visible indicator to indicate when the total current is within a predetermined amount of current from the current rating.

In another aspect of the present disclosure, the visible indicator is an LED, and wherein causing an indicator to indicate when the total current is within a predetermined amount of current from the current rating includes causing an LED to flash at a rate or to change color based on a difference between the total current and the current rating of the power strip.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the present invention may be more readily understood by one skilled in the art with reference being had to the following detailed description of several embodiments thereof, taken in conjunction with the accompanying drawings wherein like elements are designated by identical reference numerals throughout the several views, and in which:

FIG. 1 depicts a perspective view of an example embodiment of a power strip using a LED indicator in accordance with the present disclosure;

FIG. 2 depicts a perspective view of an example embodiment of a power strip using a multiple LED indicator in accordance with the present disclosure;

FIG. 3 depicts a perspective view of an example embodiment of a power strip using a bar graph indicator in accordance with the present disclosure;

FIG. 4 depicts a schematic diagram of an example embodiment of a current monitoring and signal indication circuit incorporated into the power strip of FIG. 1; and

FIG. 5 is a flow chart illustrating a method of managing an electrical load of a power strip in accordance with the present disclosure.

The figures depict embodiments of the present disclosure for purposes of illustration only. One skilled in the art will readily recognize from the following description that alternative embodiments of the structures and methods illustrated herein may be employed without departing from the principles of the present disclosure described herein.

### DETAILED DESCRIPTION

The present disclosure is directed to systems and methods for managing an electrical load of a power strip. Embodiments of the present disclosure are described herein below with reference to the accompanying drawings. However, it is to be understood that the disclosed embodiments are merely exemplary of the disclosure and may be embodied in various forms. Well-known functions or constructions are not described in detail to avoid obscuring the present disclosure in unnecessary detail. Therefore, specific structural and functional details disclosed herein are not to be interpreted as limiting, but merely as a basis for the claims and as a representative basis for teaching one skilled in the art to variously employ the present disclosure in virtually any appropriately detailed structure.

For the purposes of promoting an understanding of the principles of the present disclosure, reference will now be made to the exemplary embodiments illustrated in the drawings, and specific language will be used to describe the same. It will nevertheless be understood that no limitation of the scope of the present disclosure is thereby intended. Any alterations and further modifications of the inventive features illustrated herein, and any additional applications of the principles of the present disclosure as illustrated herein, which would occur to one skilled in the relevant art and having possession of this disclosure, are to be considered within the scope of the present disclosure.

Line voltage refers to a voltage, typically Alternating Current (AC), that is supplied to buildings/residences (e.g., electric light and power), for example, 110 VAC, 115 VAC, 120 VAC, 125 VAC, 208 VAC, 220 VAC, 230 VAC, 240 VAC, single or multiphase. Line voltage is typically made available to the end user standard plug/outlet configurations standardized by the National Electrical Manufacturers' Association (NEMA) configurations. One such standardized configuration is a NEMA 5-15 configuration which denotes a nominal 125 VAC/15 Amp outlet.

A power strip refers to a block of electrical sockets that is powered by a single electrical socket. The power strip may also be referred to as an extension block, power board, power bar, plug board, trailing gang, trailing socket, plug bar, trailer lead, multi-socket, multi-box, multiple socket, multiple outlet, a polysocket, or other terms known to those skilled in the art of power strips.

One of the critical requirements for some medical device applications is to have an uninterrupted power source. As several medical devices can share the same power source, it is important for the total consumption current to stay below the power circuit rated current. Otherwise, the circuit current limiter (breaker or similar) may be triggered and power disconnected. It is not easy in practice to predict or estimate the combined current for devices sharing the same source. In some embodiments, the systems and methods of the present disclosure warns a user when the power circuit current reaches a percentage (e.g., 75%) of the circuit rated current limit, helping the user to manage the circuit load and prevent power loss due to an overload condition. The warning may be indicated, for example, by a current monitoring light changing from green to red. The warning may be indicated in other ways as described below.

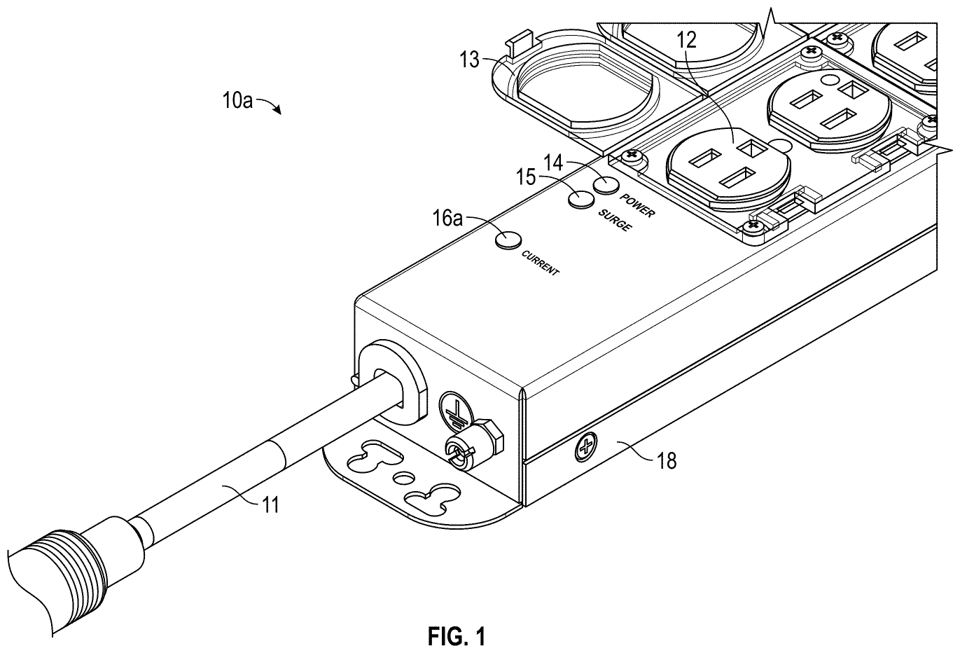

FIGS. 1-3 depict perspective views of power strips 10a-c, which may be medical-grade power strips, in accordance with the present disclosure. In an embodiment, the power cord 11 is plugged into an AC power source, e.g., an AC power receptacle electrically coupled to an electrical power system, which supplies AC power to the power strips 10a-c. It is contemplated that the electrical power source is a residential or commercial electrical power grid, a solar power source, an AC generator, or any other suitable power supply. Power is indicated using a power indicator 14, such as a light emitting diode (LED). Medical devices, such as those used in an operating room of a hospital, or in a patient's room, may be plugged in to one or more of the outlet sockets 12 located along a surface on the power strip chassis 18. The power strip 10 may include a lockable cover 13 for every outlet socket 12, which can keep debris or other particles out of the outlet sockets 12, and can be used to discourage users from plugging in additional devices. The lockable cover 13 may include a tab or other locking mechanism that is unlocked by utilizing a key or an appropriate tool.

If the current consumption of the attached devices exceeds the maximum current rating of the power strip 10, then the surge indicator light 15 turns on. In some applications, however, power must be continuously supplied to electrical devices without any interruption. For example, many medical devices must operate without interruption (e.g., a mechanical ventilator, which is also known as a “breathing machine”).

To ensure that a power strip continuously supplies power to electrical devices, a current monitoring circuit according to embodiments of the present disclosure determines whether the current drawn by the devices plugged into the outlet sockets 12 exceeds one or more predetermined current thresholds (e.g., 75%, 85%, and/or 95%) that are less than the maximum current rating of the power strip. For example, if the current draw exceeds the predetermined threshold, a single light-emitting diode (LED) 16a, multiple LEDs 16b, or an electronic or LED bar graph 16c provide an indication of the total current with respect to a current rating of the power strip. It is contemplated that this indication could also be provided by a multicolored LED, a tricolor LED, a bicolor LED, a single color LED, a display, or any other indicator known by those skilled in the art.

For example, if the measured current is below the predetermined threshold, the controller may turn on the green element of the multicolor LED 16a. If the power strip is operated at or above the predetermined threshold, the controller may turn on the red element of the multicolor LED 16a. In embodiments, the multicolor LED 16a may be an RGB LED that is controlled to display any desired colors, for example, green, yellow, and red. In other embodiments, the LED or LEDs 16a, 16b may be configured to flash according to a predetermined pattern to indicate a difference between the measured total current and a current rating of the power strip.

In one embodiment, the LED 16a flashes at a rate or changes color in a way that is related to how close the measured total current is to the predetermined threshold or the current rating (e.g., maximum current rating) of the power strip. For example, if the threshold is 75% of the maximum current rating of the power strip and the measured total current is 0% to 60%, the LED 16a is turned off (or is maintained in the off state) or, in an implementation where the LED 16a is a multicolor LED, the green LED of the LED 16a is turned on. If the measured total current is between 60% and 75% of the maximum current rating of the power strip, the LED 16a flashes at a slow rate (e.g., one flash every 0.5 seconds) or, in the implementation where the LED 16a is a multicolor LED, the red and green LEDs of the LED 16a are turned on so that the LED 16a displays a yellow color. If the measured total current is 75% or greater, the LED 16a flashes at a fast rate (e.g., one flash every 0.25 seconds) or, in the implementation where the LED 16a is a multicolor LED, the red LED of the LED 16a is turned on.

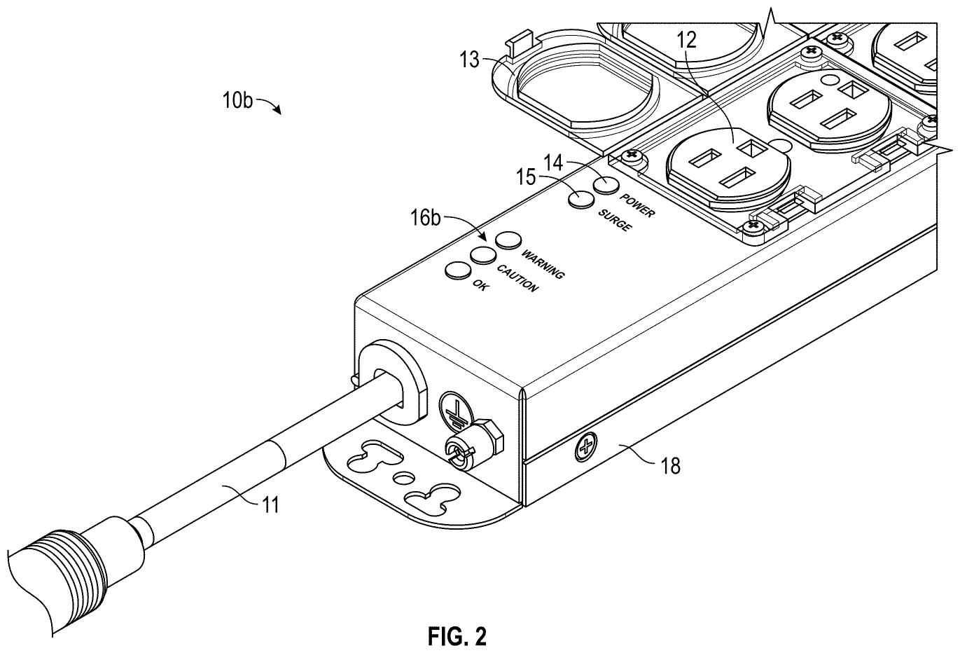

With reference to FIG. 2, in an example embodiment, the multiple LEDs 16b can be comprised of three LEDS. The three LEDs may be different colors, for example, red, yellow, and green. The multiple LEDs 16b may have a green LED for measured total current that is below the predetermined threshold by a predetermined margin of safety. For example, if the threshold is 75% of the maximum current rating of the power strip and the measured total current is between 0% and 60% of the current rating (e.g., maximum current rating) of the power strip, the green LED is turned on. Continuing the example, if the measured total current is between 60% and 75% of the current rating of the power strip, the yellow LED of the multiple LEDs 16b is turned on. Then, if the measured total current is equal to or greater than 75%, the red LED of the multiple LEDs 16b is turned on, thereby alerting a user that the power strip 10 is being operated at or above 75% of the current rating of the power strip and that the user should consider whether it is safe to plug one or more additional devices into the power strip or should not plug any additional devices into the power strip.

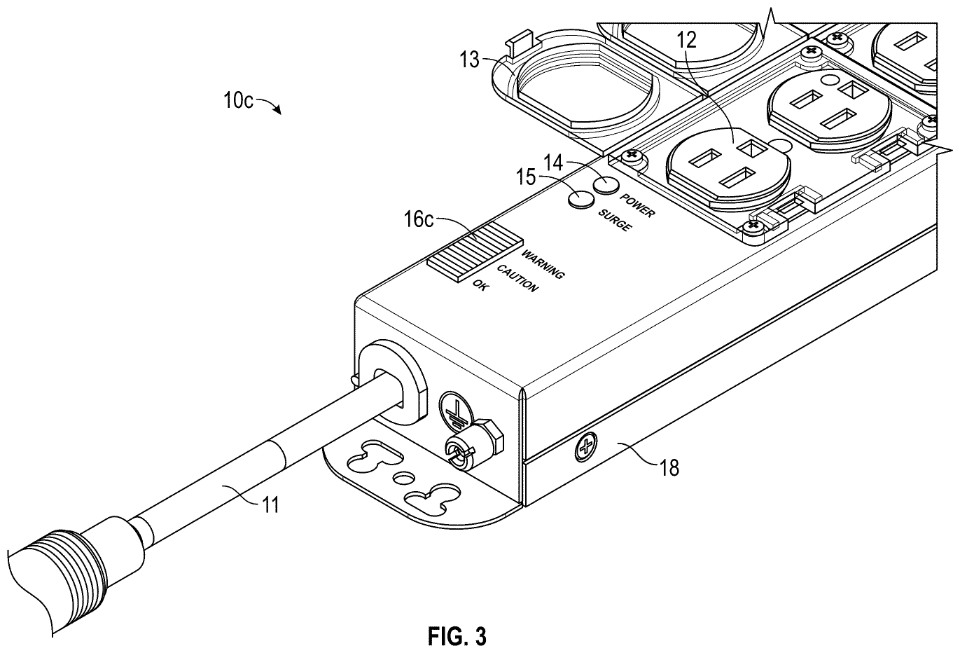

With reference to FIG. 3, in an example embodiment, a bar graph 16c may provide an indication of how close the measured total current flowing between the electrical connector and the outlet sockets of the power strip is to the maximum current capacity or the rated current of the power strip. It is contemplated that the bar graph 16c may include several colors or gradients of colors. The bar graph 16c may illuminate its green bars for a current consumption that is below the predetermined threshold by a predetermined margin of safety, e.g., a predetermined margin of safety appropriate for a given medical application or context. For example, in the case where the threshold is 75% of the current rating of the power strip, if the measured total current is less than 60% of the current rating of the power strip, the green bars are illuminated. Then, if the total measured current is between 60% and 75% of the current rating, the yellow bars of the bar graph 16c are illuminated. If the measured total current exceeds 75% of the current rating, the red bars of the bar graph 16c red indicators are illuminated, alerting a user that the power strip 10 is being operated at or above 75% of the rated current of the power strip.

It is contemplated that the indication of how close the total current is to the current capacity or current rating of the power strip may include an audio alert. For example, if a user plugs in a device and the measured total current is near or above the predetermined current threshold, an audio alert will sound until the measured total current drops below the predetermined current threshold. In another embodiment, the indication of how close the measured total current is to the current rating of the power strip (e.g., the difference between the measured total current and the current rating of the power strip) may be displayed as a message (e.g., a message including alphanumeric or numeric characters) or a graphical object (e.g., a percentage bar diagram similar to a thermometer or progress bar) on a display, such as an LED or LCD display. The message may include a message indicating that a device plugged into one of the outlet sockets should be unplugged, a message indicating that a device should not be plugged into one of the outlets sockets, or a message indicating that the power consumption of a device plugged into one of the outlet sockets should be reduced.

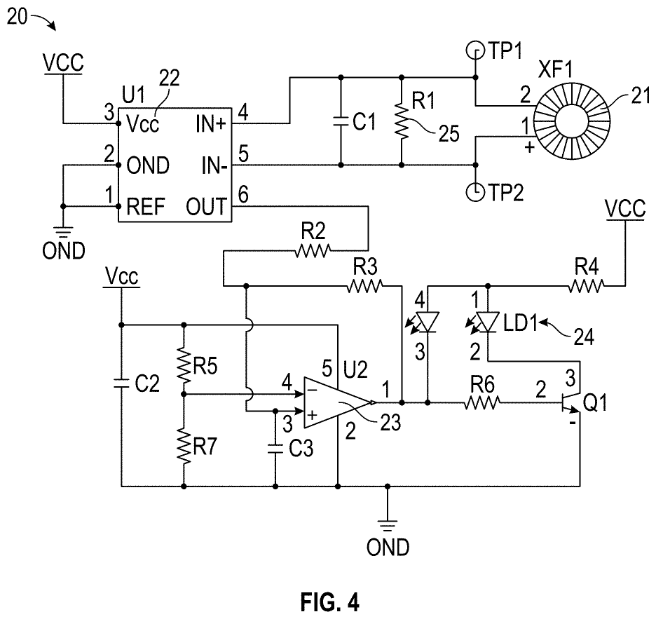

FIG. 4 depicts a schematic of an example embodiment of the current monitoring circuit 20 of FIG. 1. The current monitoring circuit 20 includes a toroidal core coil 21 configured to measure total current flowing between the power cord 11 and the outlet sockets 12. Typical current transformers are wound around a toroidal metal core, through which the current-carrying cable is passed. It is contemplated that other current detection circuits or sensors can be used to detect the total current drawn through a power strip. For example, a resistor, a current transformer, a Hall effect sensor, or a Rogowski coil can be used to measure the total current draw. A Hall effect sensor responds to the magnetic field generated around the current-carrying conductor, and produces an output voltage proportional to the current flowing in the conductor. A resistor 25, which is disposed across the coil, is used to convert the coil current to the voltage drop across the resistor 25. An amplifier 22 is configured to amplify the voltage drop across the resistor 25. This amplified voltage is further processed by a comparator 23.

The comparator 23 is configured to determine whether the total current exceeds a predetermined current threshold. A voltage divider may be used to set the predetermined current. When the comparator 23 determines that the measured total current exceeds the predetermined current threshold, a signal is generated to activate an indicator device 24. For example, when the current measured by a current transformer remains below the predetermined current threshold, the comparator output voltage remains low and turns on a green LED. When the current measured by the current transformer reaches the predetermined current threshold, the comparator output voltage changes to high and turns off the green LED and activates a transistor that turns on the red LED. It is contemplated that several stages of the comparator 23 can be used so as to allow for several current thresholds to be set, thus allowing indication of predetermined ranges of current draw so that a user can know how close the measured total current is to the current capacity or rating of the power strip and act accordingly, e.g., unplug a device from the power strip and plug the device into another power strip or reduce the use of a device. It is contemplated that the comparator circuit, amplifier, and/or the other circuitry described above may be replaced by and/or all or a portion of the functionality described above may be implemented by a microcontroller or other similar processing circuit or unit, such as a central processing unit and memory, a digital signal processor, an application specific integrated circuit, or a field programmable gate array.

In another embodiment, when the current measured by a current transformer remains below the predetermined current threshold, the comparator output remains low and turns on the green LED. When the current measured by the current transformer approaches the predetermined threshold, e.g., the measured current is within 10% of the predetermined threshold, the output of a second comparator (not shown) goes high and is summed with the output of the first comparator 23, resulting in a low voltage that turns off the green LED and activates a transistor that turns on a red LED. Additionally or alternatively, the indication of how close the measured total current is to the current capacity or rating of the power strip may be an audio signal that is transmitted or communicated to an audio speaker or a device that includes an audio speaker, e.g., a smartphone or other mobile computing device. For example, the audio signal could increase in amplitude and/or frequency as the total current approaches and exceeds the predetermined threshold or as the difference between the total current and the current rating decreases. Conversely, the audio signal could decrease in amplitude and/or frequency as the measured total current decreases to approach and drop below the predetermined threshold or as the difference between the measured total current and the current capacity increases. The predetermined threshold may be a percentage of the current rating.

In some implementations, a communication circuit is coupled to the current monitoring circuit 20 and provides an indicator signal to, for example, mobile device(s), network(s), or computer system(s) when the total current is within a predetermined amount of current from or exceeds the current rating.

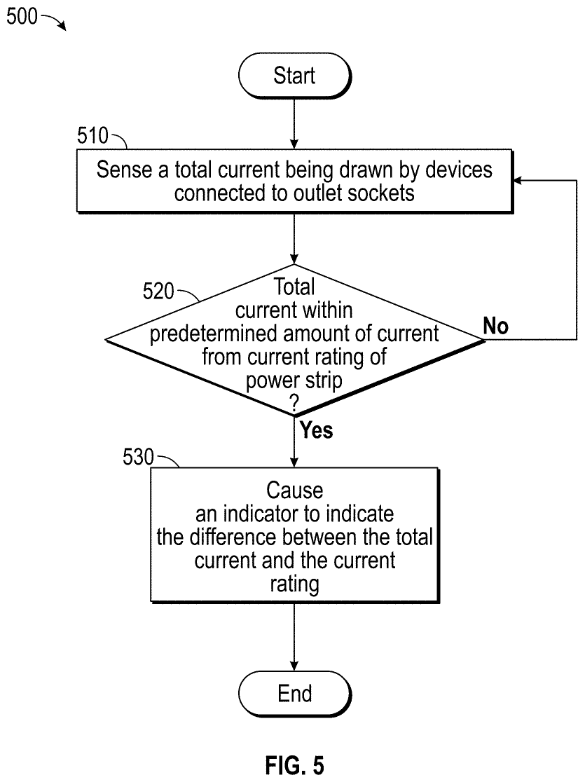

FIG. 5 is a flowchart illustrating a method 500 of managing an electrical load of a power strip in accordance with the present disclosure. The method 500 includes various blocks in an ordered sequence. However, those skilled in the art will appreciate that one or more blocks of the method 500 may be performed in a different order, repeated, and/or omitted without departing from the scope of the present disclosure.

The method 500 begins with the current monitoring circuit 20 sensing a total current being drawn by loads, e.g., electrical or electronic devices, connected to the one or more electrical outlet sockets 12, at block 510. At block 520, the current monitoring circuit 20 determines whether the total current is within a predetermined amount of current from a current rating of the power strip. The current monitoring circuit 20 may determine whether the total current is within a predetermined amount of current from a current rating by determining whether the total current is within a current range below the current rating or exceeds a predetermined threshold below the current rating. The predetermined threshold may be, for example, a percentage of the current rating of the power strip 10. For example, the power strip could be rated for 15 Amperes or 20 Amperes. Therefore, the predetermined threshold may be 15 Amperes for a 20 Ampere-rated power strip 10, for example.

If it is determined, e.g., by a comparator of the current monitoring circuit 20, that the total current exceeds a predetermined threshold (“Yes” at block 520), then, at block 530, the system causes an indicator to indicate the difference between the total current and the current rating of the power strip 10. For example, the indicator may activate an LED 16a. If it is determined that the current does not exceed the predetermined threshold (“No” at block 520), then, at block 510, the current monitoring circuit 20 electrically coupled with the electrical outlet sockets 12 continues to measure a total current being drawn by a load. In another embodiment, the current monitoring circuit 20 is configured to interface to an electronic or LED bar graph or an alphanumeric display (e.g., an LED or LCD display) mounted on the power strip so that the current monitoring circuit 20 can transmit a signal to cause the bar graph or display to indicate whether the measured total current exceeds the predetermined threshold or the difference between the measured total current and the predetermined threshold.

In another embodiment, the current monitoring circuit 20 is configured to wirelessly communicate indication signals to a wireless device, e.g., via Zigbee, Wi-fi, Bluetooth®, etc., to the Cloud, or a remote network or remote computer, for monitoring the status of the power strip. It is contemplated that the signal could be communicated to a device, e.g., a computer or mobile computing device, with a display or dashboard for monitoring multiple power strips 10.

In another aspect of the present disclosure, the indication signal includes a message indicating that a device plugged into one of the outlet sockets should be unplugged, a message indicating that a device should not be plugged into one of the plurality of outlets sockets, or a message indicating that the power consumption of a device plugged into one of the plurality of outlet sockets should be reduced.

In another aspect of the present disclosure, the controllers and/or circuitry of the power strip 10 can automatically disconnect one or more electrical outlet sockets 12 from a power source based on preset priority levels assigned to the outlet sockets 12, in order to prevent an overcurrent condition. The power strip 10 can then notify a user that the one or more electrical outlet sockets is disconnected from the power source using an appropriate indicator device, e.g., one or more light-emitting diodes (LEDs), and audio speaker, or an LCD or LED display.

While several embodiments of the disclosure have been shown in the drawings, it is not intended that the disclosure be limited thereto, as it is intended that the disclosure be as broad in scope as the art will allow and that the specification be read likewise. Any combination of the above embodiments is also envisioned and is within the scope of the appended claims. Therefore, the above description should not be construed as limiting, but merely as exemplifications of particular embodiments. Those skilled in the art will envision other modifications within the scope of the claims appended hereto.

1. A power strip comprising:
an electrical connector configured to connect to an AC power supply;
a plurality of outlet sockets electrically coupled to the electrical connector;
a conductive path between the electrical connector and the plurality of outlet sockets;
an indicator; and
a current monitoring circuit electrically coupled to the conductive path and configured to:
measure total current flowing through the conductive path;
determine whether the total current is within a predetermined amount of current from a current rating of the power strip; and
cause the indicator to indicate when the total current is within a predetermined amount of current from the current rating.

2. The power strip of claim 1, wherein the current monitoring circuit is configured to determine whether the total current is within the predetermined amount of current by determining whether the total current exceeds a predetermined threshold, and
wherein the predetermined threshold is a percentage of the current rating of the power strip.

3. The power strip of claim 2, wherein the predetermined threshold is a first predetermined threshold, and
wherein the current monitoring circuit is further configured to:
determine whether the total current exceeds a second predetermined threshold less than the first predetermined threshold; and
cause the indicator to indicate that the total current exceeds the second predetermined threshold.

4. The power strip of claim 3, wherein the current monitoring circuit is further configured to:
determine whether the total current exceeds a third predetermined threshold current that is lower than the second predetermined threshold; and
cause the indicator to indicate that the total current exceeds the third predetermined threshold.

5. The power strip of claim 1, wherein the current rating of the power strip is a maximum current rating.

6. The power strip of claim 1, wherein the current monitoring circuit comprises a current sensor, an amplifier, and a comparator, and
wherein the current sensor is electrically coupled to the conductive path and the amplifier is electrically coupled to the current sensor and the comparator.

7. The power strip of claim 1, wherein the current monitoring circuit comprises one or more of a resistor, a current transformer, a Hall effect sensor, or a Rogowski coil.

8. The power strip of claim 1, wherein the indicator is an audible or a visible indicator.

9. The power strip of claim 1, wherein the indicator is an LED configured to flash at a rate or change color based on a difference between the total current and the current rating of the power strip.

10. The power strip of claim 1, further comprising a communication circuit coupled to the current monitoring circuit and configured to provide an indicator signal to a mobile device, a network, or a computer system when the total current is within a predetermined amount of current from the current rating.

11. The power strip of claim 1, wherein the power strip is a medical-grade power strip.

12. The power strip of claim 1, wherein the current monitoring circuit is further configured to:
determine whether the total current is not within the predetermined amount of current from the current rating; and
cause the indicator to indicate that the total current is not within the predetermined amount of current from the current rating.

13. The power strip of claim 1, further comprising a plurality of lockable covers configured to cover the plurality of outlet sockets, respectively.

14. The power strip of claim 1, further comprising a circuit breaker configured to break the conductive path if an over current condition is detected.

15. A method of managing an electrical load of a power strip:
sensing a total current flowing in a conductive path coupling a plurality of outlet sockets to an electrical connector of the power strip;
determining whether the total current is within a predetermined amount of current from a current rating of the power strip; and
causing an indicator to indicate when the total current is within a predetermined amount of current from the current rating.

16. The method of claim 15, wherein sensing the total current includes amplifying a sensor signal, and
wherein determining whether the total current is within a predetermined amount of current includes comparing the amplified sensor signal to a predetermined threshold to determine whether the total current exceeds a predetermined threshold.

17. The method of claim 16, further comprising providing an indicator signal to a mobile device, a network, or a computer system when the total current is within a predetermined amount of current from the current rating.

18. The method of claim 16, further comprising:
determining whether the total current is not within the predetermined amount of current from the current rating; and
causing the indicator to indicate that the total current is not within the predetermined amount of current from the current rating.

19. The method of claim 15, wherein sensing total current includes sensing total current using a current sensor, an amplifier, and a comparator, wherein the current sensor is electrically coupled to the conductive path and the amplifier is electrically coupled to the current sensor and the comparator.

20. The method of claim 15, wherein causing an indicator to indicate when the total current is within a predetermined amount of current from the current rating includes causing an audible or a visible indicator to indicate when the total current is within a predetermined amount of current from the current rating.

21. The method of claim 20, wherein the visible indicator is an LED, and
wherein causing an indicator to indicate when the total current is within a predetermined amount of current from the current rating includes causing an LED to flash at a rate or to change color based on a difference between the total current and the current rating of the power strip.
